(19) United States
(12) Patent Application Publication
(10) Pub. No.: US 2024/0431217 A1
(43) Pub. Date: Dec. 26, 2024

(54) INCORPORATING CONSTRICTION JOSEPHSON JUNCTIONS IN SUPERCONDUCTING QUBITS FOR A SINGLE PATTERNING STEP FABRICATION

(71) Applicant: U.S. Department of Energy, Washington, DC (US)

(72) Inventors: Charles T. Black, New York, NY (US); Mingzhao Liu, Syosset, NY (US)

(21) Appl. No.: 18/388,272

(22) Filed: Nov. 9, 2023

Related U.S. Application Data
(60) Provisional application No. 63/383,063, filed on Nov. 9, 2022.

(51) Int. Cl. H10N 60/80; H01P 3/12; H01P 7/06; H10N 60/01; H10N 60/12; H10N 60/85

(52) U.S. Cl. CPC H10N 60/805; H01P 3/121; H01P 7/065; H10N 60/0912; H10N 60/12; H10N 60/85

(57) ABSTRACT

One or more embodiments relate to a superconducting qubit architecture that can be fabricated in one standard patterning step such as a lithographical step for example. Specifically, embodiments relates to a superconductor-constriction-superconductor Josephson junction (ScS JJ) qubit device for use in a quantum information processing environment. In one or more embodiments, the qubit device includes a substrate (a semiconductor substrate, an insulator substrate, and a dielectric substrate for example); a first superconducting pad formed on the substrate; and a second superconducting pad formed on the substrate, where the second superconducting pad coupled to and coplanar with the first superconducting pad.

### CROSS-REFERENCE TO RELATED APPLICATION

This application claims the benefit of and priority to U.S. Patent Application Ser. No. 63/383,063 filed Nov. 9, 2022, the complete subject matter of which is incorporated herein.

### STATEMENT OF GOVERNMENT SUPPORT

The United States Government has rights in this invention pursuant to Contract Number DE-SC0012704 between the U.S. Department of Energy and Brookhaven National Laboratory.

### FIELD OF THE INVENTION

Embodiments relate generally to the electrical, electronic, and computer arts. More specifically embodiments relate to Josephson junctions (JJs) and their applications in the field of superconducting solid-state electronic circuits.

### BACKGROUND

Embodiments relate to Josephson junctions (JJs) and their applications in the field of superconducting solid-state electronic circuits.

The superconducting qubit is a leading platform for quantum computing. The core of a known superconducting qubit is one or more superconductor/insulator/superconductor Josephson junctions (SIS JJs), which are typically formed from a thin film sandwich structure of aluminum, aluminum oxide, aluminum (Al/AlOx/Al). A variety of qubit implementations have been achieved by coupling the JJs to different electronic elements so that a two-level system with an energy gap of a few GHz is formed. To date, a common implementation is the transmon qubit, in which the JJ is shunted by a large capacitor to minimize the sensitivity to charge noise. The qubit is typically further coupled to a high-Q microwave resonator that enables the readout of qubit states in the dispersive regime. Both the shunting capacitor and the resonator are fabricated from a thin film of superconductor deposited on an insulating substrate with low dielectric loss. Although the Josephson junctions are most often based on aluminum, a superconductor with critical temperature (T_{C}) typically around 1.4 K; the shunting capacitors and the microwave resonators are often made from other superconductors, such as for example, niobium (T_{C}=9.2 K), tantalum (T_{C}=4.4 K), and titanium nitride (T_{C}=5.6 K).

The fabrication of a full superconducting qubit device typically involves at least two lithography steps. FIG. 1A depicts a conventional transmon qubit device generally designated 10. In the conventional device 10, the Al/AlOx/Al SIS Josephson junction 12 includes Al 14 and AlOx 16 in a sandwich structure (See the enlarged partial view depicted in FIG. 1B). The SIS Josephson 12 is fabricated in a patterning step separated with the rest of the device 10, including the microwave waveguide 18, microwave resonator 20, and the shunting capacitor 22.

The microwave resonator 20 and/or the shunting capacitor 22 are patterned and fabricated using photolithography or electron beam lithography. After that, lithography is used to define and fabricate the Al/AlOx/Al sandwich structure 12 that is coupled to the capacitor. Different methods have been developed for this, but generally the methods involve depositing the top and bottom Al layers 14 from two different angles relative to the substrate 24. After depositing the first Al layer 14, the structure is exposed to a controlled level of oxygen to form a thin, insulating AlOx layer 16. This method for JJ creation has been refined over many years and is a primary reason that aluminum is the choice for the qubit JJ element. However, use of this double-angle metallization method has made it challenging to scale up the fabrication of transmon qubits to desired quantities for larger-scale quantum computers. To further complicate the process, during the JJ fabrication, the capacitor/resonator elements that were fabricated at first using lithography are inevitably exposed to air, leading to the formation of a thin layer of native oxide over their surfaces. Therefore, an extra process must be used, e.g., ion milling, to remove the native oxide layer before the JJ deposition, to ensure strong metallic superconductor-to-superconductor contact between the structures.

It is to be understood that the term “metal” is used above from a physics perspective to refer to those elements having a partially filled conduction band and having lower resistance toward lower temperature. Thus, a superconducting metal silicide would also be considered a metal.

A Josephson junction is a quantum mechanical device which is comprised of two superconducting electrodes separated by a thin barrier (e.g., insulating tunnel barrier, non-superconducting metal, semiconductor, ferromagnet, etc.). The devices are named after Brian Josephson, who predicted in 1962 that pairs of superconducting electrons could essentially “tunnel” through the non-superconducting barrier from one superconductor to another. Electronic circuits can be built from Josephson junctions, especially digital logic circuitry. Many researchers are working on building ultrafast computers using Josephson logic.

Superconducting solid-state electronic circuits based on Josephson-effect nonlinear oscillators may be used in qubit implementations for quantum computing. Aluminum may be the desired superconductor despite having a relatively low superconducting transition temperature (TC) (e.g., about 1.2 degrees Kelvin) and narrow superconducting energy gap (e.g., about 44 gigahertz (GHz)). A transmon is a type of superconducting charge qubit that was designed to have reduced sensitivity to charge noise. A transmon device architecture implemented using aluminum (Al)/aluminum oxide (AlOx)/Al junctions, has been studied and is the basis of current qubit technology. However, conventional transmon implementations have limited prospects for scaling. Moreover, achieving high quality superconductor-silicon interfaces, and identifying compatible superconductors with higher TC and other tunable attributes, remains a challenge.

### SUMMARY

A need exists in the art for fabricating co-planar superconductor-constriction-superconductor Josephson junctions (ScS JJs) for qubit devices in one lithography step and transmons based on the ScS Josephson junctions prepared by the single lithography step method.

Embodiments include the use of co-planar, superconductor-constriction-superconductor (ScS) Josephson junctions prepared by the one-step method for qubit devices and the ability to fabricate complete superconducting qubit devices, including the Josephson junctions, shunting capacitors, microwave resonators, waveguides, and other peripheral components using as one step lithography method. Because only one lithography step is involved, other steps to achieve superconductor “bonding” between components made from conventional, multiple-step lithography procedure are rendered unnecessary.

Embodiments of the present invention provide a superconducting qubit architecture that can be fabricated in one standard patterning step such as a lithographical step for example. This has the benefit of being a greatly simplified technique that involves only one standard patterning step. The superconducting qubit in this architecture is fabricated on a semiconductor, insulator, or dielectric substrate, such as, but not exclusive to, sapphire or silicon, and features co-planar superconductor-constriction-superconductor type JJ or JJs (Scs JJ(s)), rather than the conventional sandwich SIS type. The co-planar ScS JJ features two separate superconductor (SC) pads that are connected by a thin neck or bridge of the same superconductor, which is also known as a “constriction” (See FIG. 2) which illustrates the layout of a co-planar ScS JJ is shown. The fact that the junction is co-planar enables it to be patterned and fabricated together with the rest of the qubit device. ScS transmon architecture introduces additional resistance against charge noise compared to traditional architectures, compensating for its lower anharmonicity.

Due to the presence of this constriction, a difference in superconducting phases can be established between the two SC pads, thus enabling its operation as a Josephson junction. The co-planar ScS JJs may be fabricated simultaneously with the superconductor capacitors and microwave resonators, which are also co-planar, from the same type of thin film superconductor, involving a single patterning step. The thin film superconductor can be chosen from a variety of superconducting materials, such as, but not exclusive to, Al, Nb, Ta, TiN, NbN, TaN, and a number of different superconductor transition metal silicides (TMSis), such as CoSi2, PtSi, and V₃Si and the like.

In accordance with embodiments of the present method, there may be variants for the single step fabrication of the qubit architecture.

In one embodiment of the present method, a featureless superconducting film may be first fabricated over the insulator/dielectric substrate using vapor phase deposition. The superconductor can either be the deposited material (such as Al, Nb, or Ta and the like), formed by deposition of the material and subsequent reaction (e.g., oxidation or nitridation), or formed from a reaction between the deposited thin film and the substrate. An example for the last case is the formation of CoSi₂, a silicide superconductor, between deposited Co film and underlying Si substrate by heating (silicidation). A layer of patterning photoresist or e-beam resist is then cast over the superconducting film, with the qubit pattern (containing all components including the JJs, capacitors, resonators, and waveguides) defined by photolithography, e-beam lithography, direct laser writing, or other patterning methods. The pattern can then be transferred to the superconducting film using techniques including, but not exclusive to, wet chemical etching, reactive ion etching (RIE), and ion milling. The final device may be completed with the solvent removal of the residual patterning resists.

In another embodiment of the present method, the substrate may be first covered with the resist, with the qubit pattern defined using the same techniques as the first variant. After resist patterning, the superconducting material may be deposited over the patterned substrate. The final device is completed with the solvent lift-off of the resists and the deposits over the resists. Depending on the desired choice of superconducting material, the superconductor can be formed after liftoff by subsequent reaction (oxidation, nitridation) or reaction with the substrate (silicidation), described above.

As may be used herein, “facilitating” an action includes performing the action, making the action easier, helping to carry the action out, or causing the action to be performed. Thus, by way of example only and without limitation, in the context of a semiconductor fabrication methodology, steps performed by one entity might facilitate an action carried out by another entity to cause or aid the desired action(s) to be performed. For the avoidance of doubt, where an actor facilitates an action by other than performing the action, the action is nevertheless performed by some entity or combination of entities.

These and other features and advantages of the present invention will become apparent from the following detailed description of illustrative embodiments thereof, which is to be read in connection with the accompanying drawings

One or more embodiments relate to a superconductor-constriction-superconductor Josephson junction (ScS JJ) qubit device for use in a quantum information processing environment. In one or more embodiments, the qubit device includes a substrate (a semiconductor substrate, an insulator substrate, and a dielectric substrate for example); a first superconducting pad formed on the substrate; and a second superconducting pad formed on the substrate, where the second superconducting pad coupled to and coplanar with the first superconducting pad.

The ScS JJ includes a thin neck or bridge of material alternatively referred to as a constriction (having a coherence length of about 10 nm for example, although different lengths are contemplated) coupled to and coplanar with the first superconducting pad and the second superconducting pad. In at least one embodiment, the first superconducting pad, the second superconducting pad, and the thin bridge are comprised of the same thin film superconducting material, where the thin film superconducting material is selected from the group consisting of Al, Nb, Ta, TiN, NbN, CoSi2, PtSi, V₃Si and the like.

In one or more embodiments include a transmon qubit device having a ScS JJ similar to that described above. The transmon qubit device further includes addition to a shunting capacitor in communication with the ScS JJ qubit device, a microwave resonator in communication with at least one of the shunting capacitor and the ScS JJ qubit device; and a microwave waveguide in communication with the microwave resonator. In one or more embodiments, the shunting capacitor, the microwave resonator, and the microwave waveguide are formed on a with the ScS JJ qubit device; such that they are all coplanar.

One or more embodiments relates to a method of forming a superconducting device including ScS JJ qubit device for use in a quantum information processing environment. The method includes depositing a featureless superconducting film on a semiconductor substrate; casting a pattern resist of the superconducting device including the ScS JJ over the superconducting film; transferring the pattern resist to the superconducting film; and removing any residual pattern resist forming the superconducting device.

In one or more embodiments, forming the superconducting device pattern in the pattern resist includes using one of the group consisting of photolithography, e-beam lithography, and direct laser writing. Embodiments include transferring the pattern resist to the superconducting film using a method selected from the group consisting of wet chemical etching, reactive ion etching, and ion milling.

Still another embodiment relates to another method of forming a superconducting device including a ScS JJ qubit device for use in a quantum computing environment. The method includes covering a semiconductor substrate with a pattern resist of the superconducting device including the ScS JJ forming a patterned substrate; depositing a thin film superconducting material over the patterned substrate; and lifting off the pattern resist and thin film superconducting material deposited on the pattern resist using a solvent.

### BRIEF DESCRIPTION OF THE DRAWINGS

The invention together with the above and other objects and advantages will be best understood from the following detailed description of the preferred embodiment of the invention shown in the accompanying drawings, wherein:

FIG. 1A depicts a layout of a known transmon qubit device having an Al/AlOx/Al SIS Josephson junction, in a sandwich structure illustrated in the enlarged partial view shown in FIG. 1B;

FIG. 2A depicts a layout of a co-planar superconductor-constriction-superconductor Josephson junction (ScS JJ), FIG. 2B depicts a layout of a transmon qubit device having a ScS JJ of FIG. 2A, in a structure illustrated in the enlarged partial view shown in FIG. 2C;

FIGS. 3A-3B depict a plot illustrating anharmonicity of an ScS transmon that is about half of an SIS transmon at the same EJ/EC ratio, at both charge neutral (ng=0) shown in FIG. 3A and charge degenerate (ng=1/2) points shown in FIG. 3B;

FIG. 4 depicts a plot illustrating an ScS transmon with a significantly smaller charge dispersion than an SIS transmon at the same EJ/EC ratio, thus compensating its lower anharmonicity;

FIG. 5 depicts a view of superconducting transition metal silicides, coherent interface (CoSi2/Si) and long coherence length for constriction type JJ;

FIG. 6 depicts a table illustrating various silicides and their corresponding T_{C}(K);

FIG. 7A depicts a view of CoSi2 with a 1 micron spacing, while FIG. 7B depicts a plot illustrating ϕ/ϕ0 versus Ic (mA);

FIG. 8 depicts a plot illustrating T(K) versus R/RN;

FIG. 9 depicts an image of Si and CoSi₂;

FIG. 10 depicts an illustration of Kulik-Omelyanchuk (KO-1) model;

FIG. 11 depicts the CPR of a nanobridge junction that is distorted from the sinusoidal function;

FIG. 12A depicts a plot of the CPR of a ScS Josephson junction in the KO-1 limit (solid red) is distorted from the sinusoidal form of a SIS junction (dashed black) while FIG. 12B depicts a plot of the Josephson energy of a ScS transmon (solid red) deviates from the cosine form of a SIS transmon (dashed black) and has 50% smaller anharmonicity at its lowest order (ϕ⁴). A harmonic parabola, ϕ²/2, is displayed (dotted cyan) for reference;

FIGS. 13A-13B depict plots illustrating; the eigenenergies (blue lines and numbers) and the probability densities (/ψ/²) of the first 4 eigenstates of a SIS transmon (FIG. 13A) and a ScS transmon (FIG. 13B), both with Eⱼ/E_{c}=20 and n_{g}=½, where the corresponding potential energies, normalized by Eⱼ, are plotted in red lines for both transmons;

FIG. 14A depicts a plot illustrating transition energy E₀ₘ=Eₘ−E₀ at n_{g}=½, FIG. 14B depicts a plot illustrating oscillator anharmonicity (E₁₂−E₀₁) at ng=½, as functions of E_{J}/E_{C} for ScS transmon (solid lines) and SIS transmon (dashed lines), and FIG. 14C depicts a plot illustrating the minimal pulse duration (τₚ) of ScS (solid line) and SIS transmons (dashed line) vs. E_{J}/EC, all operated at ω₀₁=2π×10 GHz;s

FIG. 15 depicts a plot illustrating a plot of ϕ/Π versus E_{J}(ϕ)/E_{J};

FIG. 16A depicts a plot illustrating the eigenenergies Eₘ of the lowest 3 eigenstates (m=0, 1, 2) of a ScS transmon (solid line) and a SIS transmon (dashed lines), both with E_{J}/E_{C}=10, as functions of the offset charge n_{g}, FIG. 16B depicts a plot illustrating the charge dispersion Eₘ of the lowest 3 eigenstates of a ScS transmon (solid line) and a SIS transmon (dashed lines), as functions of E_{J}/E_{C}. and

FIG. 16C depicts a plot illustrating the dephasing time T₂ of ScS (solid line) and SIS transmons (dashed line) vs. E_{J}/E_{C}, all operated at ω₀₁=2π×10 GHz.;

FIGS. 17A-17D depict plots illustrating various plots related to numerical solutions using the finite element method;

FIG. 18 a graphical guide for designing ScS transmon with required EJ and EC to match desired transmon frequency ω01 and minimum pulse duration τp. The red lines are contours lines for transmon frequencies set at values between 1 and 10 GHz. The dashed black lines are contours lines for τₚ set at a few values between 0.32 and 10 ns. The blue lines are contours lines for E_{J}/E_{C} ratios set at 10, 100, and 1000 with a second x-axis that is parallel to EC is presented for CΣ, following CΣ=e²/2EC and a second y-axis that is parallel to EJ is presented for Rn/Tc, following Rn/Tc=1.76 kBϕ0/(4eEJ);

FIGS. 19A-19B depict plots illustrating the first eigenenergies of a SIS transmon, plotted versus E_{J}/E_{C}, for n_{g}=½, calculated using the analytical solutions (gray solid lines) and the finite difference method (dashed lines), as functions of E_{J}/E_{C} with relative errors of the finite difference solutions, calculated as (E_{m,fd}−E_{m,a})/E_{m,a}, in which E_{m,fd} and E_{m,a} are the mth eigenenergies given by the finite difference method and the analytical solution, respectively;

FIG. 20 depicts a plot illustrating numerical solutions match analytical solutions for SIS;

FIGS. 21A-21D depict plots illustrating numerical solutions of eigenvalues for ScS junction;

FIG. 22 shows a plot of illustrating E_{J}/E_{C} versus E₀ₘ/E_{C};

FIG. 23 depicts a plot illustrating charge dispersion in plot for SIS compared with ScS;

FIG. 24 depicts a plot illustrating how ScS has a lower charge dispersion than SIS transmon, from the higher tunnel barrier;

FIG. 25 depicts a plot illustrating the effect on coherence time T2;

FIG. 26 depicts a plot illustrating anharmonicity of ScS transmon;

FIG. 27 depicts a plot illustrating anharmonicity of ScS transmon;

FIG. 28A depicts the CPR of a nanobridge junction is distorted from the sinusoidal function; while FIG. 28B depicts the CPRs of two nanobridge arms in a SQUID that do not form perfect interference when their phase difference equals π, leaving a residual current through the SQUID;

FIG. 29A depicts the Josephson energy of a nanobridge transmon that deviates from the cosine form of a regular SIS transmon and has 50% smaller anharmonicity at the lowest order (ϕ4) (a parabola, ϕ2/2, is displayed as a reference to the effect of anharmonicity); while FIG. 29B depicts the Josephson energies of two nanobridge arms in a SQUID that do not cancel out when their phase difference equals π, leaving a residual term as specified by Eq. 6, with its minima located at ϕ=(k+½)π;

FIG. 30 depicts a flowchart illustrating one method of forming a transom device having an ScS JJ qubit device; and

FIG. 31 depicts a flowchart illustrating another method of forming a transom device having an ScS JJ qubit device.

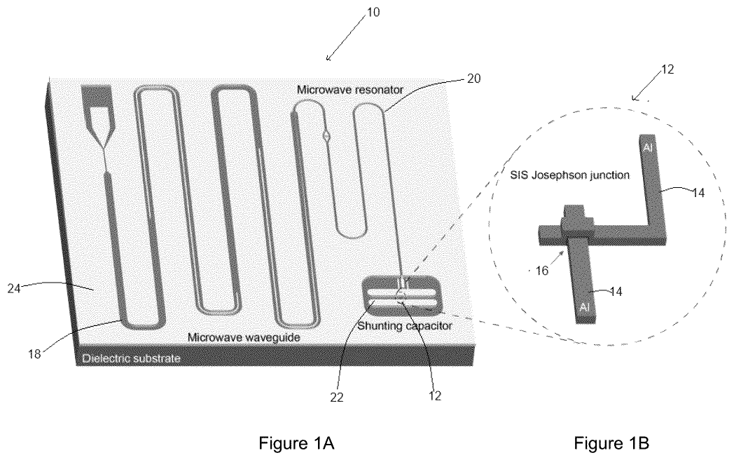

It should be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

The foregoing summary, as well as the following detailed description should be read with reference to the drawings in which similar elements in different drawings are numbered the same. The drawings, which are not necessarily to scale, depict illustrative embodiments and are not intended to limit the scope of the invention.

One or more principles of the present invention, as manifested in one or more embodiments thereof, will be described herein in the context of illustrative co-planar superconductor-constriction-superconductor type Josephson junction(s) ScS JJs. and methods for fabricating co-planar ScS JJs for qubit devices and transmons based on the ScS JJs prepared by the single lithography step method, which have beneficial application, for example, as transmon qubits in a quantum computing environment. It is to be appreciated, however, that the invention is not limited to the specific structures and/or methods illustratively shown and described herein. Rather, it will become apparent to those skilled in the art given the teachings herein that numerous modifications can be made to the embodiments shown that are within the scope of the claimed invention. That is, no limitations with respect to the embodiments shown and described herein are intended or should be inferred.

As previously stated, in a quantum computing or information processing environment, superconducting solid-state electronic circuits and/or devices based on Josephson-effect nonlinear oscillators may be used in qubit implementations. However, conventional transmon implementations, which may form the basis of qubit technology, generally have limited prospects for scaling.

In order to overcome the one or more disadvantages exhibited by conventional qubit device implementations, the present methods, as manifested in one or more embodiments, relates to methods for fabricating co-planar ScS JJs for qubit devices and transmons based on the ScS JJs prepared by the single lithography step method. By way of illustration only and without limitation, one or more of the accompanying figures depict exemplary processing steps/stages in the fabrication of a superconducting qubit device structure according to embodiments of the invention.

One or more embodiments relate to a superconducting qubit architecture that can be fabricated in a greatly simplified technique that involves only one standard lithographical patterning step. The superconducting qubit in this architecture is fabricated on a substrate (semiconductor, insulator, or dielectric substrate), such as, but not exclusive to, sapphire or silicon, and features co-planar superconductor-constriction-superconductor (ScS JJ) type, rather than the conventional sandwich SIS type. The co-planar ScS JJ features two separate superconductor pads that are connected by a thin neck or bridge of the same superconductor material, which is alternatively known as a “constriction”. Because of the presence of this constriction, a difference in superconducting phases can be established between the two pads, thus enabling its operation as a Josephson junction. The co-planar ScS JJs will be fabricated simultaneously with the superconductor capacitors and microwave resonators, which are also co-planar, from the same type of thin film superconductor, involving a single patterning step. The thin film superconductor can be chosen from a variety of superconducting materials, such as, but not exclusive to, Al, Nb, Ta, TiN, NbN, TaN, and a number of different superconductor transition metal silicides, such as CoSi2, PtSi, and V₃Si.

More specifically, one or more embodiments relate to a superconducting qubit architecture that can be fabricated in a greatly simplified technique that involves only one standard lithographical patterning step.

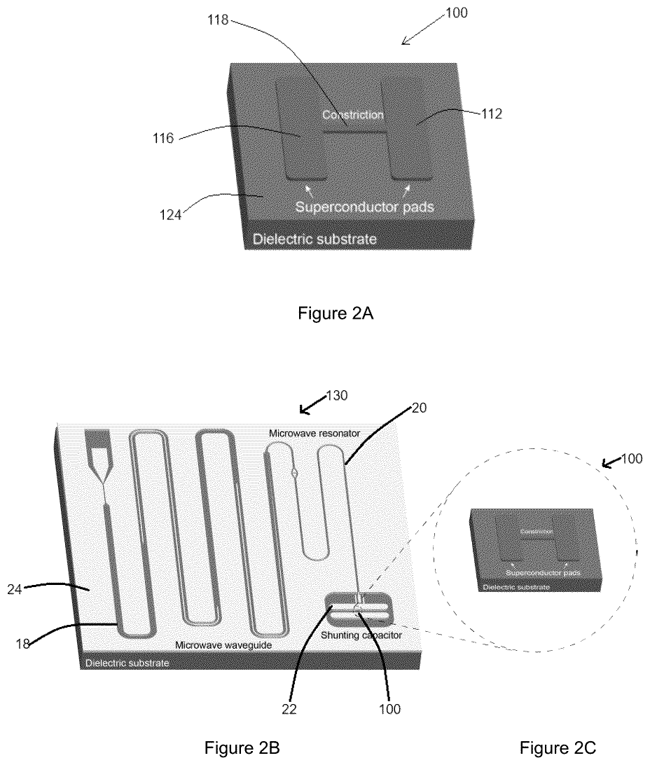

FIG. 2A depicts one or more embodiments relating to a superconductor-constriction-superconductor Josephson junction (ScS JJ) qubit device 100 for use in a quantum information processing environment. In one or more embodiments, the qubit device 100 includes a substrate 124 (a semiconductor substrate, an insulator substrate, and a dielectric substrate for example); a first superconducting pad 112 formed on the substrate 124; and a second superconducting pad 116 formed on the substrate 124, where the second superconducting pad 116 is coupled to and coplanar with the first superconducting pad 112.

The ScS JJ includes a thin neck or bridge of material 118 alternatively referred to as a constriction (having a coherence length of about 10 nm for example, although different lengths are contemplated) coupled to and coplanar with the first superconducting pad 112 and the second superconducting pad 116. In at least one embodiment, the first superconducting pad 112, the second superconducting pad 116, and the thin bridge 118 are comprised of the same thin film superconducting material, where the thin film superconducting material is selected from the group consisting of Al, Nb, Ta, TiN, NbN, CoSi2, PtSi, V₃Si and the like.

As illustrated in FIGS. 2B-2C, one or more embodiments include a transmon qubit device 130 having a ScS JJ qubit device 100 similar to that described above and illustrated in FIG. 2A. The transmon qubit device 130 illustrated in FIG. 2B-2C further includes, in addition to the ScS JJ qubit device 100 a shunting capacitor 22 in communication with the ScS JJ qubit device 100, a microwave resonator 20 in communication with at least one of the shunting capacitor 22 and the ScS JJ qubit device 100; and a microwave waveguide 18 in communication with the microwave resonator 20. In one or more embodiments, the shunting capacitor, the microwave resonator, and the microwave waveguide are formed with the ScS JJ qubit device; such that they are all coplanar.

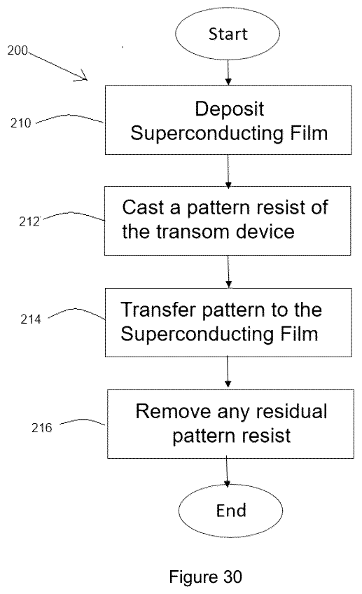

One or more embodiments relates to a method 200 of forming a superconducting device including ScS JJ qubit device for use in a quantum information processing environment as shown in FIG. 30. The method includes depositing a featureless superconducting film on a semiconductor substrate 210; and casting a pattern resist of the superconducting device including the ScS JJ over the superconducting film 212. Method 200 further includes transferring the pattern resist to the superconducting film 214; and removing any residual pattern resist forming the superconducting device 216.

In one or more embodiments, method 200 includes forming the superconducting device pattern in the pattern resist using at least one of the group consisting of photolithography, e-beam lithography, and direct laser writing. Embodiments include transferring the pattern resist to the superconducting film using a method selected from the group consisting of wet chemical etching, reactive ion etching, and ion milling.

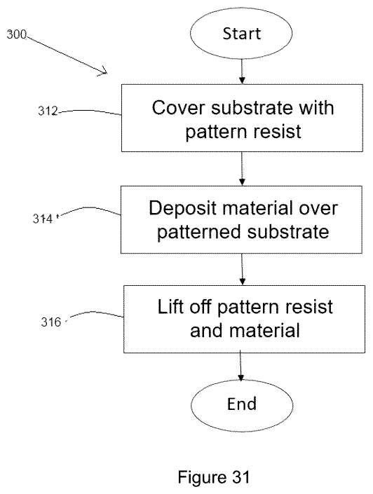

Still another embodiment relates to another method 300 of forming a superconducting device including a ScS JJ qubit device for use in a quantum computing environment illustrated in FIG. 31. The method 300 includes covering a semiconductor substrate with a pattern resist of the superconducting device including the ScS JJ forming a patterned substrate 312; depositing a thin film superconducting material over the patterned substrate 314; and lifting off the pattern resist and thin film superconducting material deposited on the pattern resist using a solvent 316.

As provided previously, there are at least two variants for the single-step fabrication of this qubit architecture. In the first variant (See FIG. 30 for example), a featureless superconducting film will be first fabricated over the insulator/dielectric substrate using vapor phase deposition. The superconductor can either be the deposited material (such as Al, Nb, or Ta), formed by deposition of the material and subsequent reaction (e.g., oxidation or nitridation), or formed from a reaction between the deposited thin film and the substrate. An example for the last case is the formation of CoSi₂, a silicide superconductor, between deposited Co film and underlying Si substrate by heating (silicidation). A layer of patterning photoresist or e-beam resist is then cast over the superconducting film, with the qubit pattern (containing all components including the JJs, capacitors, resonators, and waveguides) defined by photolithography, e-beam lithography, direct laser writing, or other patterning methods. The pattern can then be transferred to the superconducting film using techniques including, but not exclusive to, wet chemical etching, reactive ion etching (RIE), and ion milling. The final device is completed with the solvent removal of the residual patterning resists.

In the second variant (See FIG. 31 for example), the substrate will be first covered with the resist, with the qubit pattern defined using the same techniques as the first variant. After resist patterning, the superconducting material will be deposited over the patterned substrate. The final device is completed with the solvent lift-off of the resists and the deposits over the resists. Depending on choice of superconducting material, the superconductor can be formed after liftoff by subsequent reaction (oxidation, nitridation) or reaction with the substrate (silicidation), described above.

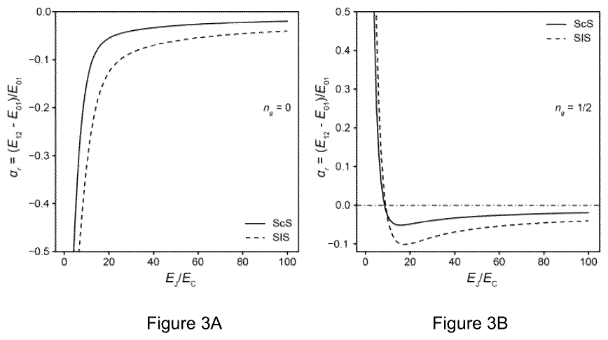

Based on existing transport theory, ScS JJs has a different current-phase relationship from SIS JJs. As a result, a transmon based on nanobridge ScS junction has 50% less anharmonicity than a conventional SIS transmon for the same Ej/Ec ratio. FIGS. 3A-3B depict plots illustrating anharmonicity of an ScS transmon that is about half of an SIS transmon at the same EJ/EC ratio, at both charge neutral (ng=0) shown in FIG. 3A and charge degenerate (ng=½) points shown in FIG. 3B.

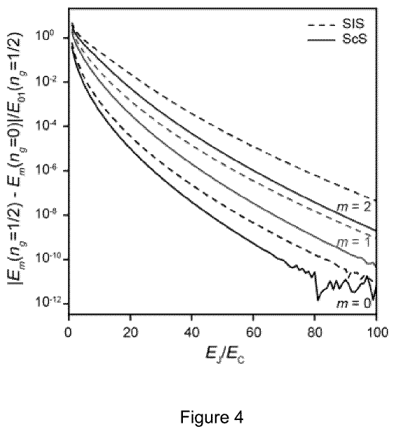

It should be appreciated that the lowered anharmonicity is accompanied by a lowered charge dispersion (for the same Ej/Ec ratio), meaning that the ScS transmon architecture is more resistant against charge noise when the other operation parameters are kept the same. FIG. 4 depicts a plot illustrating an ScS transmon that has a significantly smaller charge dispersion than an SIS transmon at the same EJ/EC ratio, thus compensating its lower anharmonicity. The compensation suggests advantages to the ScS transmon for practical application, albeit at different optimal operation parameters.

For a transmon operated at ω01=2π×10 GHz, a typical pulse duration of 10 ns requires a relative anharmonicity of 1/200π, corresponding to 10<E_{J}/E_{C}<12000, which defines the range of device parameters for good qubit operation. Considering that ω₀₁=(8E_{J}E_{C})½/ℏh, 7.4×10⁻²⁴ J<E_{J}<2.6×10⁻²² J and 7.4×10⁻²⁵ J>E_{C}>2.1×10⁻²⁶ J are required. For a typical value of E_{J}/E_{C}=100, we require E_{J}=2.3×10⁻²³ J and E_{C}=2.3×10⁻²⁵ J. For an E_{J}/E_{C}=1000, E_{J}=7.4×10⁻²³ J and E_{C}=7.4×10⁻²⁶ J are needed.

The magnitude of Josephson energy E_{J} is determined by the ScS junction's critical current Ic, following E_{J}=0.755 I_{c}ϕ0/2π. According to this relation, the critical current for should be Ic=94 nA for E_{J}/E_{C}=100 or 300 nA for E_{J}/E_{C}=1000. For constriction junction, it means that the normal state resistance should be about 3.4×Tc kΩ (for E_{J}/E_{C}=100) or 1.1×Tc kΩ (for E_{J}/E_{C}=1000), in which Tc is the superconducting critical temperature.

For example, consider a ScS junction made from a 20-nm-thick PtSi film (Tc=0.8 K), which has a sheet resistance about 50 Ω/sq and a coherence length about 800 nm. The constriction can be fabricated as a nanowire with a length of 800 nm and a width of 18 nm (for E_{J}/E_{C}=100) or 45 nm (for E_{J}/E_{C}=1000). In Table 1, estimations on junction geometries are listed, based on the choice of material. It should be noted that these numbers are only shown as examples and in practice the device can be designed within a wide range of variations. The value of E_{C} can be controlled by the area of shunting capacitance CB, following EC≈e2/2CB. It is found that CB=56 fF for E_{J}/E_{C}=100 or 180 fF for E_{J}/E_{C}=1000. The dimension of the capacitor can be readily adjusted based on its configuration, to keep the capacitance within the specified range. Constriction dimensions to match required transmon design parameters, for devices fabricated from 10-nm-thick CoSi2, 20-nm-thick PtSi, 10-nm-thick PtSi, and 6-nm-thick PtSi. Calculation based on material parameters reported by Badoz et al and Oto et al.

TABLE 1

| | CoSi₂ | PtSi | PtSi | PtSi |
|---|---|---|---|---|
| | (10 | (20 | (10 | (6 |
| | nm)* | nm)** | nm)** | nm)** |
| Sheet Resistance (Ohm/sq) | 3.9 | 20 | 67 | 178 |
| Coherence Length (nm) | 130 | 734 | 440 | 278 |
| Tc (K) | 0.85 | 0.80 | 0.60 | 0.45 |
| Rn (Ohm) (Ej/Ec = 100) | 2890 | 2720 | 2040 | 1530 |
| Rn (Ohm) (Ej/Ec = 1000) | 935 | 880 | 660 | 495 |
| Aspect Ratio (Ej/Ec = 100) | 741 | 136 | 30.5 | 8.6 |
| Aspect Ratio (Ej/Ec = 1000) | 240 | 44.0 | 9.85 | 2.78 |
| Constriction Length (nm) | 130 | 734 | 440 | 278 |
| Constriction Width (nm) | 0.18 | 5.4 | 14.5 | 32.3 |
| (Ej/Ec = 100) | | | | |
| Constriction Width (nm) | 0.54 | 17 | 45 | 100 |
| (Ej/Ec = 1000) | | | | |

*Badoz et al, Journal de Physique Lettres 46, 979 (1985)
**Oto et al, Journal of Applied Physics 76, 5339 (1994)

The value of EC can be controlled by the area of shunting capacitance CB, following EC≈e2/2CB. It was found that CB=56 fF for EJ/EC=100 or 180 fF for EJ/EC=1000. The dimension of the capacitor can be readily adjusted based on its configuration, to keep the capacitance within the specified range.

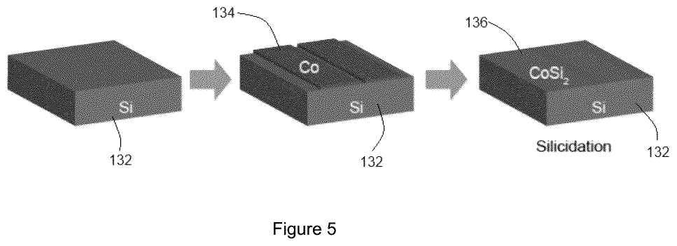

FIG. 5 depicts a view of superconducting transition metal silicides 130, a coherent interface (CoSi₂/Si) for example having a long coherence length for constriction type JJ. In one embodiment, a silicide superconductor includes a Co film 134 deposited on an underlying Si substrate 132 by heating (silicidation). A layer of patterning photoresist or e-beam resist is then cast over the superconducting film 134, with the qubit pattern (containing all components including the JJs, capacitors, resonators, and waveguides) defined by photolithography, e-beam lithography, direct laser writing, or other patterning methods.

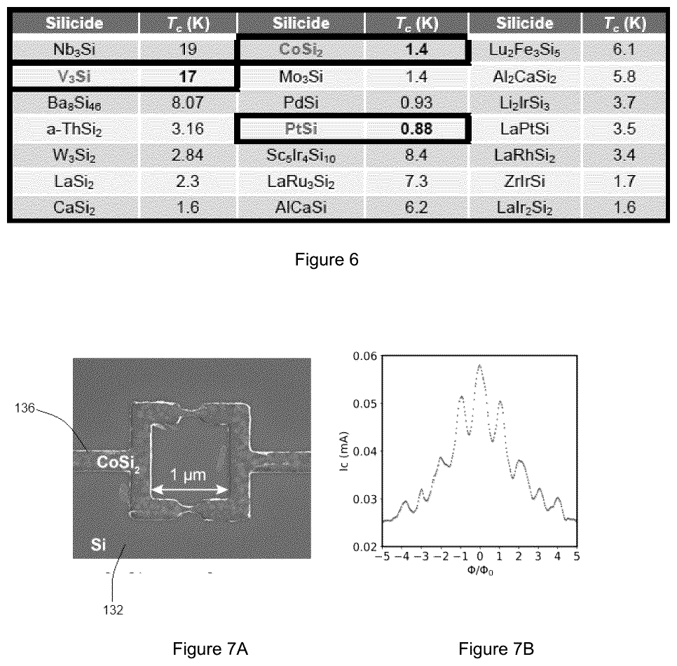

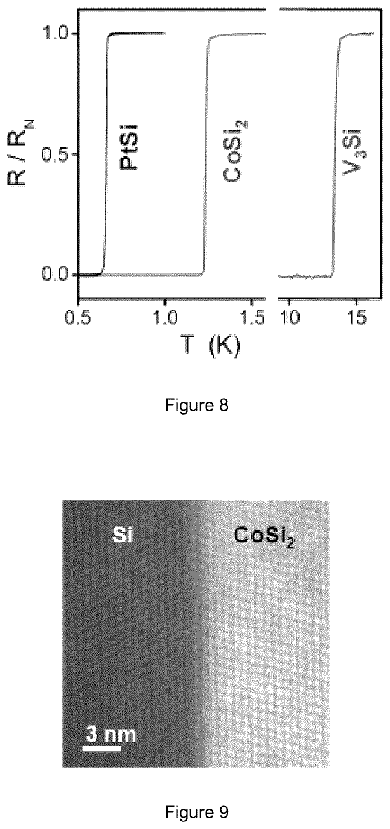

FIG. 6 depicts a table illustrating various superconducting transition metal silicides and their corresponding T_{C}(K). It illustrates a coherent interface (CoSi₂/Si) with long coherence lengths for constriction type JJ. FIG. 7A depicts a view of CoSi₂ 136 ON Si substrate 132 having a 1 micron spacing, while FIG. 7B depicts a plot illustrating ϕ/ϕ0 versus Ic (mA). FIG. 8 depicts a plot illustrating T(K) versus R/RN. FIG. 9 depicts an image of Si and CoSi2.

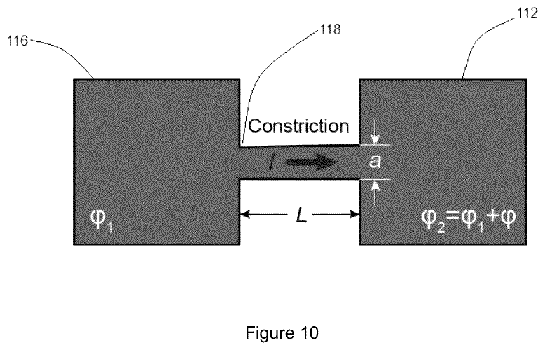

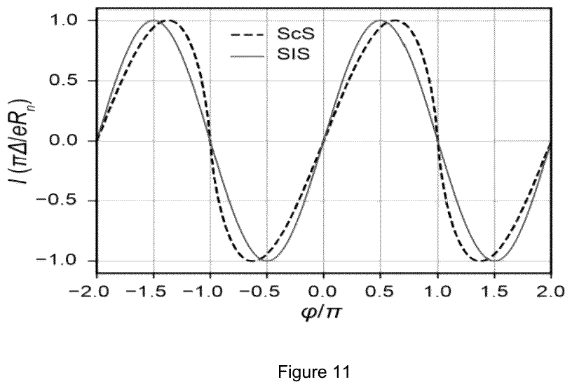

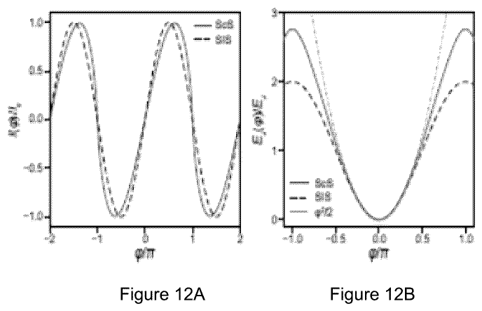

FIG. 10 depicts an illustration of Kulik-Omelyanchuk (KO-1) model. FIG. 11 depicts the CPR of a nanobridge junction that is distorted from the sinusoidal function. FIG. 12A depicts a plot of the CPR of a ScS Josephson junction in the KO-1 limit (solid red) is distorted from the sinusoidal form of a SIS junction (dashed black) while FIG. 12B depicts a plot of the Josephson energy of a ScS transmon (solid red) deviates from the cosine form of a SIS transmon (dashed black) and has 50% smaller anharmonicity at its lowest order (ϕ⁴). A harmonic parabola, ϕ²/2, is displayed (dotted cyan) for reference.

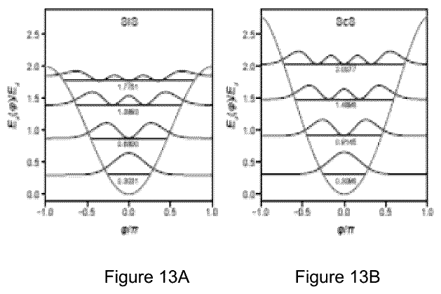

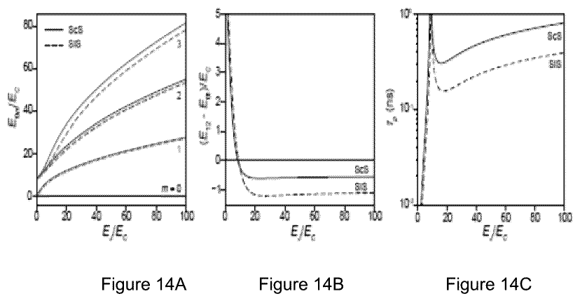

FIGS. 13A-13B depict plots illustrating; the eigenenergies (blue lines and numbers) and the probability densities (/ψ/²) of the first 4 eigenstates of a SIS transmon (FIG. 13A) and a ScS transmon (FIG. 13B), both with Eⱼ/E_{c}=20 and n_{g}=½, where the corresponding potential energies, normalized by Eⱼ, are plotted in red lines for both transmons. FIG. 14A depicts a plot illustrating transition energy E₀ₘ=Eₘ−E₀ at n_{g}=½, FIG. 14B depicts a plot illustrating oscillator anharmonicity (E₁₂−E₀₁) at n_{g}=½, as functions of E_{J}/E_{C} for ScS transmon (solid lines) and SIS transmon (dashed lines), and FIG. 14C depicts a plot illustrating the minimal pulse duration (τₚ) of ScS (solid line) and SIS transmons (dashed line) vs. E_{J}/E_{C}, all operated at ω₀₁=2π×10 GHz.

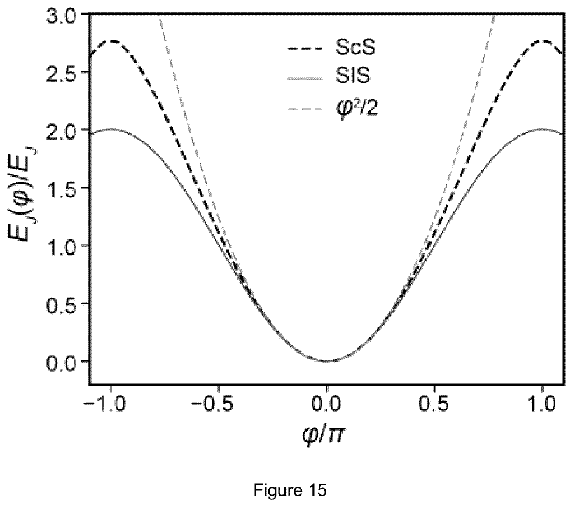

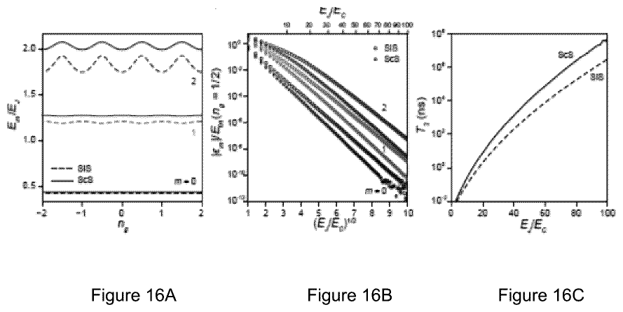

FIG. 15 depicts a plot illustrating a plot of ϕ/Π versus E_{J}(ϕ)/E_{J}. FIG. 16A depicts a plot illustrating the eigenenergies Eₘ of the lowest 3 eigenstates (m=0, 1, 2) of a ScS transmon (solid line) and a SIS transmon (dashed lines), both with E_{J}/E_{C}=10, as functions of the offset charge n_{g}, FIG. 16B depicts a plot illustrating the charge dispersion Eₘ of the lowest 3 eigenstates of a ScS transmon (solid line) and a SIS transmon (dashed lines), as functions of E_{J}/E_{C}. and FIG. 16C depicts a plot illustrating the dephasing time T₂ of ScS (solid line) and SIS transmons (dashed line) vs. E_{J}/E_{C}, all operated at ω₀₁=2π×10 GHz.

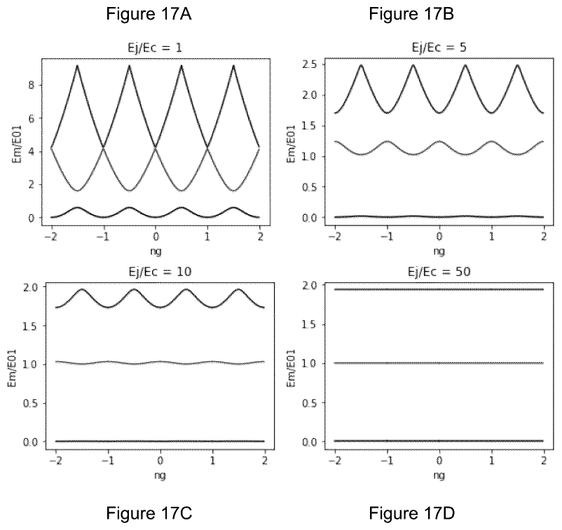

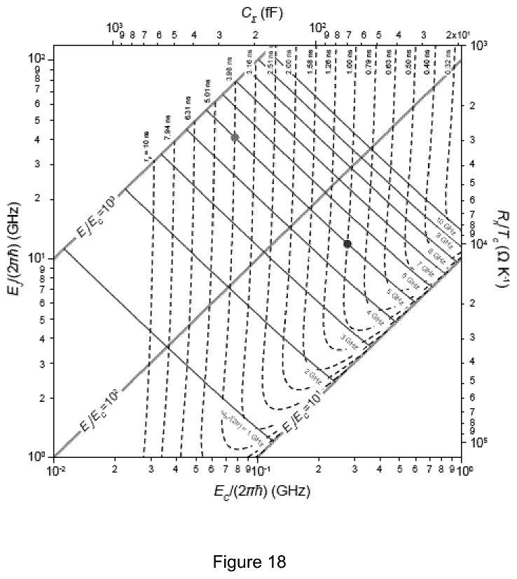

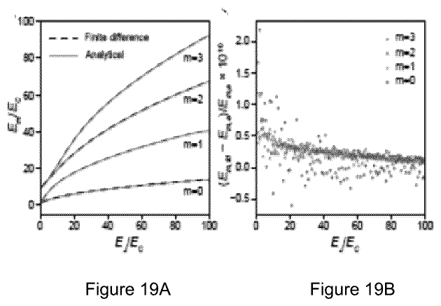

FIGS. 17A-17D depict plots illustrating various plots related to numerical solutions using the finite element method. FIG. 18 a graphical guide for designing ScS transmon with required EJ and EC to match desired transmon frequency ω01 and minimum pulse duration τₚ. The red lines are contours lines for transmon frequencies set at values between 1 and 10 GHz. The dashed black lines are contours lines for τₚ set at a few values between 0.32 and 10 ns. The blue lines are contours lines for EJ/EC ratios set at 10, 100, and 1000 with a second x-axis that is parallel to EC is presented for CZ, following CΣ=e²/2EC and a second y-axis that is parallel to EJ is presented for Rn/Tc, following Rn/Tc=1.76 kBφ0/(4eEJ). FIGS. 19A-19B depict plots illustrating the first eigenenergies of a SIS transmon, plotted versus E_{J}/E_{C}, for n_{g}=½, calculated using the analytical solutions (gray solid lines) and the finite difference method (dashed lines), as functions of E_{J}/E_{C} with relative errors of the finite difference solutions, calculated as (E_{m,fd}−E_{m,a})/E_{m,a}, in which E_{m,fd} and E_{m,a} are the mth eigenenergies given by the finite difference method and the analytical solution, respectively.

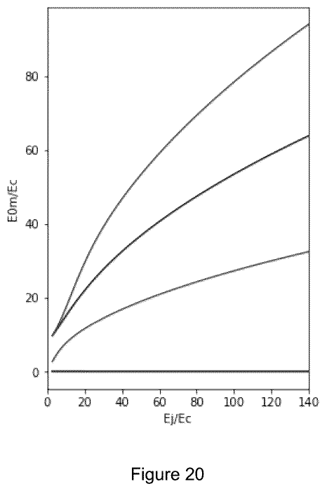

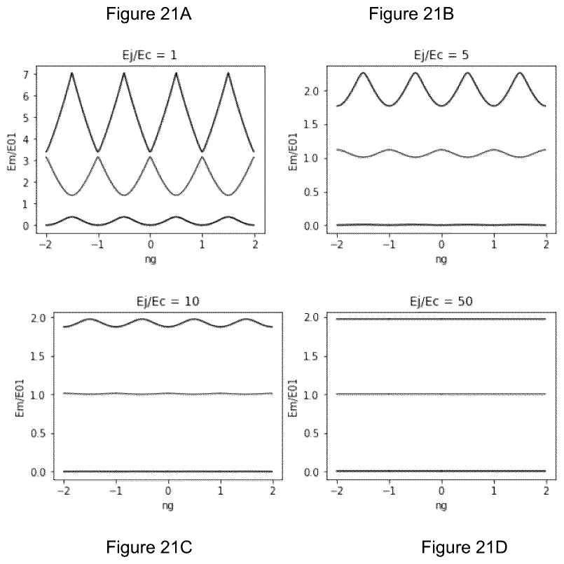

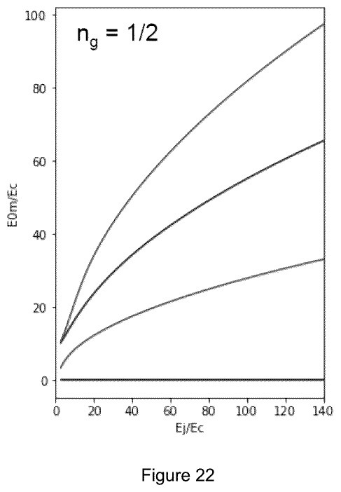

FIG. 20 depicts a plot illustrating numerical solutions match analytical solutions for SIS; FIGS. 21A-21D depict plots illustrating numerical solutions of eigenvalues for ScS junction. FIG. 22 shows a plot of illustrating E_{J}/E_{C} versus E₀ₘ/E_{C}.

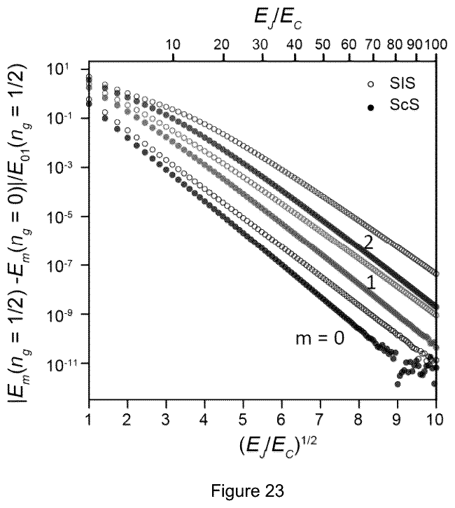

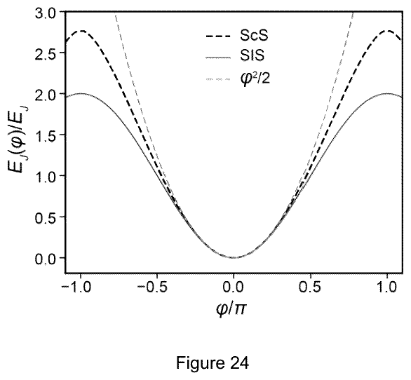

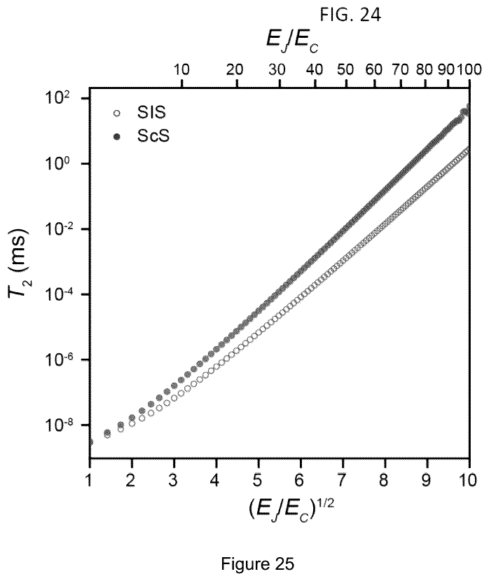

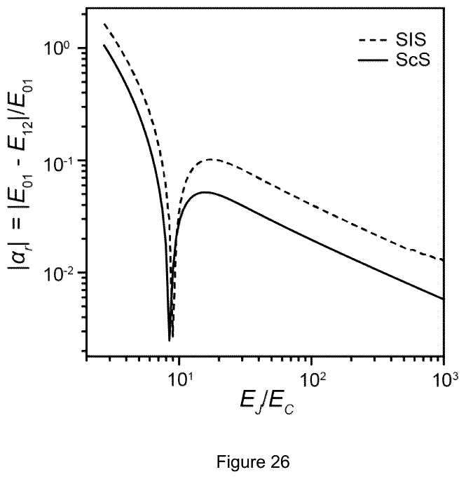

FIG. 23 depicts a plot illustrating charge dispersion in plot for SIS compared with ScS. FIG. 24 depicts a plot illustrating how ScS has a lower charge dispersion than SIS transmon, from the higher tunnel barrier. FIG. 25 depicts a plot illustrating the effect on coherence time T2. FIG. 26 depicts a plot illustrating anharmonicity of ScS transmon.

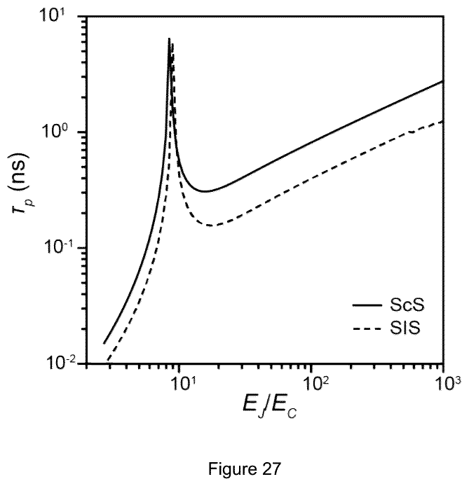

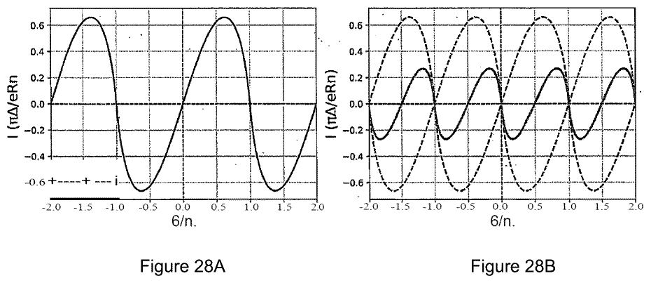

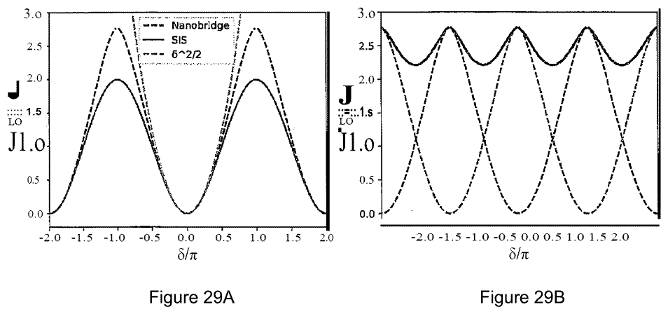

FIG. 27 depicts a plot illustrating anharmonicity of ScS transmon. FIG. 28A depicts the CPR of a nanobridge junction is distorted from the sinusoidal function; while FIG. 28B depicts the CPRs of two nanobridge arms in a SQUID that do not form perfect interference when their phase difference equals π, leaving a residual current through the SQUID. FIG. 29A depicts the Josephson energy of a nanobridge transmon that deviates from the cosine form of a regular SIS transmon and has 50% smaller anharmonicity at the lowest order (ϕ4) (a parabola, ϕ 2/2, is displayed as a reference to the effect of anharmonicity); while FIG. 29B depicts the Josephson energies of two nanobridge arms in a SQUID that do not cancel out when their phase difference equals π, leaving a residual term as specified by Eq. 6, with its minima located at ϕ=(k+½)π.

### Current-Phase Relation of a Short ScS Junction

Consider a ScS Josephson junction comprised of two large superconductors connected by diffusive quasi-one-dimensional wire with length d<<√ε₀l and width w<<d, where ξ₀ is the Pippard superconducting coherence length, and l<<ξ₀ is the dirty-limit electron mean free path. In this case, Kulik and Omelyanchuk showed that the CPR for the ScS junction (KO-1) at T=0 K is:

$${I}_{ScS} ( φ ) = \frac{πΔ}{{eR}_{n}} cos \frac{φ}{2} {tanh}^{- 1} ( sin \frac{φ}{2} ) , \qquad Eq 1$$

in which Δ is the superconducting energy gap and Rn is the normal state resistance of the junction. The junction critical current I_{c,ScS}=0.662πΔ/(eRₙ) is achieved at ϕ=(2k±0.627)π to satisfy dl(ϕ)/dϕ∝1−sin(ϕ/2)tanh⁻¹[sin(ϕ/2)]=0. Given the Maclaurin series tanh⁻¹(x)=x+x³/3+O(x⁵), Eq. 1 may be rewritten to a form that resembles the CPR of a SIS Josephson junction, as

$${I}_{ScS} ( φ ) = 0.755 {I}_{e , ScS} sin φ [ 1 + \frac{1}{3} {sin}^{2} \frac{φ}{2} + O ( {sin}^{4} \frac{φ}{2} ) ] , \qquad Eq 2$$

which shows that the CPR of a ScS junction distorts from the conventional sinusoidal form, but still bears odd parity and a 2π periodicity (See FIG. 12A).

### Josephson Energy of a ScS Transmon

The potential energy of a Josephson junction is given by the integral:

$${E}_{s} ( φ ) = \int {I}_{s} Vdt = \int {I}_{J} \frac{{Φ}_{0}}{2 π} \frac{d φ}{dt} dt = \int {I}_{J} \frac{{Φ}_{0}}{2 π} d φ . \qquad Eq 3$$

For a short junction described by Eq. 1, the integral in Eq. 3 leads to:

$${E}_{J , ScS} ( φ ) = \frac{{ΔΦ}_{0}}{2 {eR}_{n}} [ ln ( {cos}^{2} \frac{φ}{2} ) + 2 sin \frac{φ}{2} {tanh}^{- 1} ( sin \frac{φ}{2} ) ] . \qquad Eq 4$$

Although this form appears very different from the potential energy of a SIS junction,

$${E}_{J , SIS} ( φ ) = {E}_{J , SIS} ( 1 - cos φ ) , \qquad Eq 5$$

with E_{J,SIS}=I_{c,SIS}ϕ₀/2π, Maclaurin expansions of E_{J,ScS} and E_{J,SIS} make their similarities apparent:

$${E}_{J , ScS} ( φ ) = \frac{{ΔΦ}_{0}}{4 {eR}_{n}} ( \frac{1}{2} {φ}^{2} - \frac{1}{48} {φ}^{4} + O ( {φ}^{6} ) ) \\ {E}_{J , SIS} ( φ ) = {E}_{J , SIS} ( \frac{1}{2} {φ}^{2} - \frac{1}{24} {φ}^{4} + O ( {φ}^{6} ) ) . \qquad Eq 6$$

Comparing the coefficients of the harmonic (ϕ²) term, it is observed that the Josephson energy of a ScS transmon can be defined as:

$${E}_{J , ScS} = \frac{{ΔΦ}_{0}}{4 {eR}_{n}} = 0.755 {I}_{e , ScS} {Φ}_{0} / ( 2 π ) , \qquad Eq 7$$

where the last equality recognizes that I_{c,ScS}=0.662πΔ/(eRₙ). Eq. 7 shows that both potential energies contain anharmonicity led by a ϕ⁴ term, from which it is estimated that the anharmonicity of a ScS transmon is about one half that of a SIS transmon, for devices with the same E_{J}. This difference is clear when comparing normalized E_{J}(ϕ) of ScS and SIS transmons with a harmonic parabolic potential ϕ²/2 (See FIG. 12B). A more precise evaluation of the anharmonicity is provided below by computing the ScS transmon eigenenergies.

### Eigenenergies and Eigenstates of a ScS Transmon

A conventional SIS transmon has a Hamiltonian of the form:

$${\hat{H}}_{SIS} = 4 {{E}_{c} ( \hat{n} - {n}_{g} )}^{2} + {E}_{J} ( 1 - cos \hat{φ} ) , \qquad Eq 8$$

where n_{g} is the offset charge. The wave equation for a SIS transmon can be solved analytically.
In a ScS transmon, the potential energy is given by Eq. 4, so that the Hamiltonian becomes,

$${\hat{H}}_{ScS} = 4 {{E}_{C} ( \hat{n} - {n}_{g} )}^{2} + {E}_{J} [ 2 ln ( {cos}^{2} \frac{\hat{φ}}{2} ) + 4 sin \frac{\hat{φ}}{2} {tanh}^{- 1} ( sin \frac{\hat{φ}}{2} ) ] . \qquad Eq 9$$

The wave equation of a ScS transmon can be solved numerically using the finite difference method, in which the Hamiltonian is expressed in a discretized space of phase ϕ∈[−π, π), with the periodic boundary condition applied to both ends. The validity of the computation is confirmed by comparing a similar numerical solution of the wave equation for a SIS transmon with the analytical solutions presented by Koch et al. FIGS. 13A-13B compare the first 4 eigenstates of a SIS transmon and a ScS transmon, both with E_{J}/E_{C}=20 and n_{g}=½. Although the lower level eigenenergies and eigenfunctions are similar, the differences become more apparent at higher energies. This trend is more clearly observed for the transition energies E₀ₘ=Eₘ−E₀ calculated for both transmon types, across a range of E_{J}/E_{C} from 1 and 100 (See FIG. 14A). This difference reflects the smaller anharmonicity of the ScS transmon, compared to the SIS transmon. By treating the leading anharmonic term (−ϕ⁴/24) in Eq. 6 as a perturbation to the harmonic potential and applying the first-order perturbation theory, the mth eigenenergy of a SIS transmon is approximated by

$${E}_{m , SIS} \approx h {ω}_{p} ( m + \frac{1}{2} ) - \frac{{E}_{C}}{4} ( 2 {m}^{2} + 2 m + 1 ) , \qquad Eq 10$$

in which ℏωₚ=√8E_{J}E_{C} is the Josephson plasma energy. The transition energy between the (m−1)th and mth levels is therefore

$${E}_{m - 1. m . SIS} \approx h {ω}_{p} - {mE}_{C} . \qquad Eq 11$$

From Eq. 11, it is found that the anharmonicity of SIS transmon, α_{SIS}≡E_{12,SIS}−E_{01,SIS}, is approximately −E_{C}. By applying the same first-order perturbation theory calculation but recognizing that the perturbation term is half as a SIS transmon (Eq. 6), the mth eigenenergy of a ScS transmon can be approximated by

$${E}_{m , ScS} \approx h {ω}_{p} ( m + \frac{1}{2} ) - \frac{{E}_{C}}{8} ( 2 {m}^{2} + 2 m + 1 ) , \qquad Eq 12$$

so that its anharmonicity, α_{ScS}, is approximately −Ec/2, or half the anharmonicity of a SIS transmon. This can be visualized in a plot of numerical results, looking at transmons with E_{J}/E_{C}≥20 (See FIG. 14B).

The smaller anharmonicity of a ScS transmon means that the transitions E₀₁ and E₁₂ lie closer in energy, so that a longer RF pulse is needed to correctly excite the desired transition E₀₁. The minimal pulse duration can be estimated as τₚ≈ℏ|α|⁻¹. As shown in FIG. 14C, despite its lower anharmonicity, τₚ of the ScS transmon remains less than 1 ns even for E_{J}/E_{C}=100, when the qubit operates at 10 GHz. Because typical qubit pulse durations are ˜10 ns, we may conclude that the lower anharmonicity will not inhibit normal operation of a ScS transmon.

### Charge Dispersion of a ScS Transmon

A primary benefit of the transmon architecture is its relative immunity to charge noise, when designed to operate in the regime of E_{J}>>EC. In a SIS transmon, the charge dispersion of the mth level decreases exponentially with √8Ej/Ec, following

$${e}_{m} = {E}_{m} ( {n}_{g} = 1 / 2 ) - {E}_{m} ( {n}_{g} = 0 ) \approx {E}_{C} \frac{{2}^{2 m + n}}{{( - 1 )}^{m} ml} \sqrt{\frac{2}{π}} {( \frac{{E}_{J}}{2 {E}_{C}} )}^{\frac{m}{2} + \frac{n}{4}} {e}^{- \sqrt{8 {E}_{J} / {E}_{C}}} . \qquad Eq . 13$$

Intuitively, the charge dispersion is related to the tunneling probability between neighboring potential energy valleys (See FIGS. 13A-13B), e.g., when ϕ makes a full 2π rotation. By this reasoning, the higher barrier height of a ScS transmon (˜2.8E_{J} vs. 2E_{J}) may be expected to better suppress the tunneling probability and provide lower charge dispersion, compared to a SIS transmon.

FIG. 15A plots the first three eigenenergies Eₘ (m=0, 1, 2) versus the effective offset charge n_{g} for both SIS (dashed) and ScS (solid) transmons, with EJ/EC=10. Clearly, the ScS transmon eigenenergies are more weakly perturbed by n_{g}. Calculations of the charge dispersion, \acute{ε}ₘ=Eₘ(n_{g}=½)−Eₘ(n_{g}=0), across a wide range of 1≤E_{J}/E_{C}≤100 show that suppression of charge dispersion in the ScS transmon becomes more effective for larger E_{J}/E_{C} ratios (See FIG. 15B). When E_{J}/E_{C}=100, the charge dispersion of the first excited state of a ScS transmon, \acute{ε}_{1,ScS}, is over one order of magnitude less than the corresponding SIS transmon. It is noted that computation on SIS transmon matches the analytical result very well, again demonstrating the high numerical precision of the finite difference computation. Nevertheless, the computational error becomes significant as the normalized charge dispersion, |\acute{ε}ₘ|/E₀₁, approaches 10⁻¹¹ and smaller (see lower right corner of FIG. 15B). This is due to the accumulation of floating-point error that eventually shows up for evaluating the vanishing difference between the two eigenenergies at n_{g}=0 and 1/2.

In FIG. 15B, the y-axis is preset on a logarithmic scale and the x-axis is scaled as √E_{J}E_{C}, so that all curves take a linear form approaching large Ej/Ec values. For the SIS transmom, the slope matches the expected exp √8E_{J}E_{C} dependence in Eq. 13. For the ScS transmom, the slope is larger, and is best described by:

$${e}_{m} ∝ exp ( - \sqrt{1.16 \times 8 {E}_{J} / {E}_{C}} ) .$$

The improved charge dispersion makes the ScS transmon both less sensitive to charge noise and, in turn, gives it a longer dephasing time T₂. For dephasing caused by slow charge fluctuations of large amplitude, Koch et al. has found an upper limit of T₂ given by:

$${T}_{2} \approx \frac{4 h}{{e}^{2} π \vert {e}_{1} \vert} .$$

Using this relation, the T₂ for both SIS and ScS transmons is compared for Ej/Ec between 1 and 100 (See FIG. 15C). The ScS transmon improves T₂ across the entire range of E_{J}/E_{C} and especially at higher ratios. At E_{J}/E_{C}=100, the SIS transmon has a T₂ ceiling of about 3 ms, compared to about 50 ms for the ScS transmon, an over 10 fold increase. At present, because the T₁ lifetime of SIS transmon qubits is still beyond 1 ms and not limited by the charge noise, this advantage of the ScS transmon architecture will have little performance benefit. However, because we expect the lifetimes of superconducting qubits to continue improving (Schoelkopf's Law), there may be a point when charge noise dephasing becomes a bottle-neck, for which the ScS transmon architecture can offer effective mitigation.

### ScS Transmon, the Slope is Larger, and is Best Described by:

The operational behavior of a ScS transmon is determined by its E_{J} and E_{C}, which define the operating frequency ω₀₁, the relative immunity to charge noise (\acute{ε}₁), and the minimum excitation pulse duration (τₚ). Because these three quantities are determined by E_{J} and E_{C}, they are not independent. This interdependence can be visualized with three sets of contour lines plotted in the plane of E_{J} versus E_{C} (See FIG. 16). These contours represent: (1) a transmon operating frequency (ω₀₁/(2π)) between 1 and 10 GHz (set of red, descending diagonal lines), (2) ratios of E_{J}/E_{C} from 10, 100, and 1000 (set of blue, ascending diagonal lines), and the minimum excitation pulse duration τₚbetween 0.32 and 10 ns (set of dashed, predominantly vertical lines). Selecting two of these defines the third one. For example, a ScS transmon designed to operate at ω₀₁/(2π)=5 GHz and with an excitation pulse of τₚ=4 ns (green dot in FIG. 16) must have an E_{J}/E_{C} ratio of about 600. Instead, a shorter excitation pulse of τₚ=1 ns (purple dot in FIG. 16) requires a tradeoff of smaller E_{J}/E_{C}≈40, and thus less immunity against charge noise.

Importantly, E_{J} and E_{C} of a ScS transmon are set by the physical device dimensions and fundamental properties of the materials composing it. E_{J} is determined by the superconducting energy gap of the material (Δ) and the normal state resistance of the junction (Rₙ) (Eq. 7). For a BCS superconductor where Δ=1.76k_{B}T_{C}, E_{J} can be expressed in terms of the material properties Rₙ/T_{c}=1.76k_{B}ϕ₀/(4eE_{J,ScS}), which is shown as the second (right) y-axis in FIG. 16. Similarly, because E_{C} is set by the total capacitance (CΣ=e²/2E_{C,ScS}) which depends on device geometry and dielectric properties, Ec can be expressed as a capacitance, shown as a second (top) x-axis in FIG. 16.

Returning to the example, it can now be seen from FIG. 16 that designing a ScS transmon with ω₀₁/(2π)=5 GHz, τₚ=4 ns, and E_{J}/E_{C} ratio of about 600 (green dot) requires a junction with Rₙ/T_{c}≈3 kΩ K⁻¹ and capacitor with C_{Σ}≈250 fF. The properties can be realized by a constriction junction fabricated from a thin film super-conductor that has both a relatively high normal state resistivity and a long superconducting coherence length. As one example, a 10-nm-thick PtSi film has been reported with normal-state sheet resistance Rₛ=67 Ω/□, superconducting T_{c}=0.63 K, and Pippard coherence length ξ=440 nm. Using these material parameters, the ScS transmon design criteria can be met by using a constriction junction with physical length of 440 nm and width of 16 nm. The qubit capacitor physical dimensions should be designed for C_{Σ}=250 fF, according to FIG. 16. If a shorter excitation pulse time of τₚ=1 ns (purple dot) is desired, the constriction must have Rₙ/T_{c}≈10 kΩ K⁻¹ and C_{Σ}≈70 fF. For the same PtSi superconductor, these values can be met with physical length of 440 nm and width of 5 nm. which are more challenging dimensions to fabricate.

It is to be appreciated that the various layers and/or regions shown in the accompanying figures may not be drawn to scale. Furthermore, one or more semiconductor layers of a type commonly used in such semiconductor devices may not be explicitly shown in a given figure to facilitate a clearer description. This does not imply that the semiconductor layer(s) not explicitly shown are omitted in the actual device.

In one or more embodiments, the device structure is essentially a tunable quantum qubit device that integrates a Josephson tunneling junction comprising a pair of superconductor pads connected by a thin neck of the same superconductor known as a constriction.

When used in a quantum computing circuit having a plurality of qubit devices, at least a subset of the qubit devices being formed in accordance with embodiments of the invention, the independent control gates are coupled to the Josephson tunneling junctions and are reconfigurable on the fly by a user. Tunability is achieved by simultaneously modulating energy levels of the Josephson tunneling junctions with the capacitive-coupled control gates and dynamically reconfiguring the quantum computing circuit via the independent control gates. This design allows for nonvolatile, field-programmable configurations where quantum states are created and reconfigured through gate-control coupling, providing increased performance, complexity, resiliency and reduced leakage.

In one or more embodiments, formation of the exemplary device structures described herein may involve deposition of certain materials and layers by physical vapor deposition (PVD), chemical vapor deposition (CVD), atomic layer deposition (ALD), molecular beam epitaxy (MBE), or any of the various modifications thereof, including, for example, plasma-enhanced chemical vapor deposition (PECVD), metal-organic chemical vapor deposition (MOCVD), low pressure chemical vapor deposition (LPCVD), electron-beam physical vapor deposition (EB-PVD), and plasma-enhanced atomic layer deposition (PE-ALD). The depositions can be epitaxial processes, and the deposited material can be crystalline. In one or more embodiments, formation of a layer can be achieved using a single deposition process or multiple deposition processes, where, for example, a conformal layer is formed by a first process (e.g., ALD, PE-ALD, etc.) and a fill is formed by a second process (e.g., CVD, electrodeposition, PVD, etc.); the multiple deposition processes can be the same or different.

As used herein, the term “semiconductor” may refer broadly to an intrinsic semiconductor material that has been doped, that is, into which a doping agent has been introduced, giving it different electrical properties than the intrinsic semiconductor material, or it may refer to intrinsic semiconductor material that has not been doped. Doping may involve adding dopant atoms to an intrinsic semiconductor material, which thereby changes electron and hole carrier concentrations of the intrinsic semiconductor material at thermal equilibrium. Dominant carrier concentration in an extrinsic semiconductor material determines the conductivity type of the semiconductor material.

The term “metal” is intended to be used herein from a chemistry perspective to refer to the shiny, electrically conductive elements on the periodic table. This is to be distinguished from the definition of a “metal” from a physics perspective, which usually refers to those elements having a partially filled conduction band and having lower resistance toward lower temperature.

The term “gate” as used herein may refer broadly to a structure used to control output current (i.e., flow of carriers in a channel) of a semiconducting device through the application of electrical or magnetic fields.

The term “crystalline” as used herein may refer broadly to any material that is single- crystalline or multi-crystalline (i.e., polycrystalline).

The term “non-crystalline material” generally refers to any material that is not crystalline, including any material that is amorphous, nano-crystalline, or micro-crystalline.

The term “intrinsic” as used herein may refer broadly to any material which is substantially free of dopant atoms, or material in which the concentration of dopant atoms is less than a prescribed amount, such as, for example, about 10¹⁵ atoms/cm³.

As used herein, the term “insulating” may generally denote a material having a room temperature conductivity of less than about 10⁻¹⁰ (Ω−m)⁻¹.

Having described the basic concept of the embodiments, it will be apparent to those skilled in the art that the foregoing detailed disclosure is intended to be presented by way of example. Accordingly, these terms should be interpreted as indicating that insubstantial or inconsequential modifications or alterations and various improvements of the subject matter described and claimed are considered to be within the scope of the spirited embodiments as recited in the appended claims. Additionally, the recited order of the elements or sequences, or the use of numbers, letters or other designations therefor, is not intended to limit the claimed processes to any order except as may be specified. All ranges disclosed herein also encompass any and all possible sub-ranges and combinations of sub-ranges thereof. Any listed range is easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as up to, at least, greater than, less than, and the like refer to ranges which are subsequently broken down into sub-ranges as discussed above. As utilized herein, the terms “about,” “substantially,” and other similar terms are intended to have a broad meaning ins conjunction with the common and accepted usage by those having ordinary skill in the art to which the subject matter of this disclosure pertains. As utilized herein, the term “approximately equal to” shall carry the meaning of being within 15, 10, 5, 4, 3, 2, or 1 percent of the subject measurement, item, unit, or concentration, with preference given to the percent variance. It should be understood by those of skill in the art who review this disclosure that these terms are intended to allow a description of certain features described and claimed without restricting the scope of these features to the exact numerical ranges provided. Accordingly, the embodiments are limited only by the following claims and equivalents thereto. All publications and patent documents cited in this application are incorporated by reference in their entirety for all purposes to the same extent as if each individual publication or patent document were so individually denoted.

All numeric values are herein assumed to be modified by the term “about”, whether or not explicitly indicated. The term “about” generally refers to a range of numbers that one of skill in the art would consider equivalent to the recited value (e.g., having the same function or result). In many instances, the terms “about” may include numbers that are rounded to the nearest significant figure.

The recitation of numerical ranges by endpoints includes all numbers within that range (e.g., 1 to 5 includes 1, 1.5, 2, 2.75, 3, 3.80, 4, and 5).

One skilled in the art will also readily recognize that where members are grouped together in a common manner, such as in a Markush group, the present invention encompasses not only the entire group listed as a whole, but each member of the group individually and all possible subgroups of the main group. Accordingly, for all purposes, the present invention encompasses not only the main group, but also the main group absent one or more of the group members. The present invention also envisages the explicit exclusion of one or more of any of the group members in the claimed invention.

What is claimed is:

1. A superconductor-constriction-superconductor Josephson junction (ScS JJ) qubit device for use in a quantum information processing environment, the qubit device comprising:
a substrate;
a first superconducting pad formed on the substrate; and
a second superconducting pad formed on the substrate, the second superconducting pad coupled to and coplanar with the first superconducting pad.

2. The ScS JJ qubit device of claim 1 wherein the substrate is selected from the group consisting of a semiconductor substrate, an insulator substrate, and a dielectric substrate.

3. The ScS JJ qubit device of claim 1 wherein the first superconducting pad is coupled to the second superconducting pad via a thin bridge of superconducting material coplanar with the first superconducting pad and the second superconducting pad.

4. The ScS JJ qubit device of claim 3 wherein the first superconducting pad, the second superconducting pad, and the thin bridge are comprised of the same thin film superconducting material.

5. The ScS JJ qubit device of claim 4 wherein the thin film superconducting material is selected from the group consisting of Al, Nb, Ta, TiN, NbN, CoSi2, PtSi, V₃Si and the like.

6. A superconducting qubit device for use in a quantum computing environment, the superconducting qubit device comprising:
a substrate;
a superconductor-constriction-superconductor Josephson junction (ScS JJ) qubit device formed on the substrate;
a shunting capacitor formed on the substrate and in communication with the ScS JJ qubit device;
a microwave resonator formed on the substrate and in communication with at least one of the shunting capacitor and the ScS JJ qubit device; and
a microwave waveguide formed on the substrate and in communication with the microwave resonator.

7. The superconducting qubit device of claim 6 wherein the ScS JJ qubit device, the shunting capacitor, the microwave resonator, and the microwave waveguide are coplanar with each other on the substrate.

8. The superconducting qubit device of claim 6 wherein the ScS JJ qubit device comprises a first superconducting pad formed on the substrate and a second superconducting pad formed on the substrate, the second superconducting pad coupled to and coplanar with the first superconducting pad.

9. The superconducting qubit device of claim 8 wherein the first superconducting pad is coupled to the second superconducting pad via a thin bridge of superconducting material coplanar with the first superconducting pad and the second superconducting pad.

10. The superconducting qubit device of claim 9 wherein the first superconducting pad, the second superconducting pad, and the thin bridge are comprised of the same thin film superconducting material.

11. The superconducting qubit device of claim 9 further comprising the thin bridge having a coherence length of about 100 nm.

12. The superconducting qubit device of claim 10 wherein the thin film superconducting material is selected from the group consisting of Al, Nb, Ta, TiN, NbN, CoSi2, PtSi, V₃Si, and the like.

13. The superconducting qubit device of claim 6 wherein the superconducting qubit device is selected from the group consisting of a transmon qubit, a fluxonium qubit, a phase qubit, and the like.

14. A method of forming a superconducting device including a superconductor-constriction-superconductor Josephson junction (ScS JJ) qubit device for use in a quantum information processing environment, the method comprising:
depositing a featureless superconducting film on a semiconductor substrate;
casting a pattern resist of the superconducting device including the ScS JJ over the superconducting film;
transferring the pattern resist to the superconducting film; and
removing any residual pattern resist forming the superconducting device.

15. The method of claim 14 where the superconducting film is selected from the group consisting of Al, Nb, Ta, TiN, NbN, CoSi₂, PtSi, V3Si, and the like.

16. The method of claim 14 wherein the ScS JJ includes a first superconducting pad, a second superconducting pad coplanar with the first superconducting pad, and a thin bridge of superconducting material coupled to and coplanar with the first superconducting pad and the second superconducting pad.

17. The method of claim 14 further comprising forming the superconducting device pattern in the pattern resist by using one of a group consisting of photolithography, e-beam lithography, and direct laser writing.

18. The method of claim 17 wherein the superconducting device pattern includes a pattern of the ScS JJ qubit device, a shunting capacitor, a microwave resonator, and a microwave waveguide formed on the semiconductor substrate such that the ScS JJ qubit device, a shunting capacitor, a microwave resonator, and a microwave waveguide and in communication with the microwave resonator.

19. The method of claim 14 wherein the pattern resist is transferred to the superconducting film using a method selected from the group consisting of wet chemical etching, reactive ion etching, and ion milling.

20. A method of forming a superconducting device including a superconductor-constriction-superconductor Josephson junction (ScS JJ) qubit device for use in a quantum computing environment, the method comprising:
covering a semiconductor substrate with a pattern resist of the superconducting device including the ScS JJ forming a patterned substrate;
depositing a thin film superconducting material over the patterned substrate; and
lifting off the pattern resist and thin film superconducting material deposited on the pattern resist using a solvent.
